(19) United States
(12) Patent Application Publication
(10) Pub. No.: US 2014/0204199 A1
(43) Pub. Date: Jul. 24, 2014

(54) WIRING INSPECTING METHOD, WIRING INSPECTING APPARATUS, WIRING INSPECTING PROGRAM, AND RECORDING MEDIUM

(71) Applicant: SHARP KABUSHIKI KAISHA, Osaka-shi, Osaka (JP)

(72) Inventor: Eiji Yamada, Osaka-shi (JP)

(73) Assignee: SHARP KABUSHIKI KAISHA, Osaka-shi, Osaka (JP)

(21) Appl. No.: 14/237,208

(22) PCT Filed: Jul. 10, 2012
(86) PCT No.: PCT/JP2012/067629

§ 371 Date: Feb. 5, 2014

(30) Foreign Application Priority Data
Sep. 27, 2011 (JP) 2011-210295

(51) Int. Cl. G06T 7/00; H04N 5/33

(52) U.S. Cl. CPC G06T 7/0004; H04N 5/33
USPC 348/86

(57) ABSTRACT

A wiring inspecting method according to the present invention is a wiring inspecting method for inspecting presence/absence of a short-circuit portion of a wiring line formed on a substrate, including a heat generation process of generating, with voltage application means (5), heat in the short-circuit portion by applying a voltage to the wiring line; an image acquisition process of acquiring, with image capturing means (6), an infrared image of the substrate; a binarization process of generating, with image processing means (7), a binarized image from the infrared image by using a threshold; and a position specification process of specifying, with the image processing means (7), a position of the short-circuit portion by using the binarized image. In the binarization process, binarization processing is repeated by changing the threshold. Accordingly, the infrared image of the wiring line including the short-circuit portion is binarized to generate a thinned binarized image, and the position of the short-circuit portion can be accurately specified.

### TECHNICAL FIELD

The present invention relates to a wiring inspecting method, a wiring inspecting apparatus, a wiring inspecting program, and a recording medium that are suitable for detecting a short-circuit fault of a wiring line on a substrate on which a plurality of wiring lines are formed, such as an active matrix substrate used for, for example, a liquid crystal display apparatus.

### BACKGROUND ART

A liquid crystal display apparatus includes an active matrix substrate, which is one substrate member including a plurality of wiring lines, picture element electrodes, switching elements, and so forth formed thereon, and a color filter substrate, which is the other substrate member including opposite electrodes and color filters formed thereon. The liquid crystal display apparatus is manufactured by bonding the two substrates with a space therebetween, injecting a liquid crystal material into the space to form a liquid crystal layer, and mounting peripheral circuit components.

In the process of manufacturing an active matrix substrate, a fault such as a disconnection or short-circuit of a wiring line on the substrate may occur. The fault becomes a cause of a display failure of the liquid crystal display apparatus. To reduce failures such as display failures of the liquid crystal display apparatus, it is necessary to detect and repair a fault of the active matrix substrate before the above-described process of injecting a liquid crystal material.

FIG. 10 illustrates an inspecting apparatus for a wiring pattern disclosed in PTL 1. The inspecting apparatus according to PTL 1 energizes, with energizing electrodes 61, wiring patterns 53 formed on a substrate 50, causes infrared to be generated by heat generation of the wiring patterns 53, captures the infrared image thereof using an infrared sensor 63, performs image processing on an image signal, and compares the infrared image with certain reference image data, thereby inspecting failure/no-failure of the wiring patterns 53.

FIG. 11 illustrates an inspecting apparatus for an active matrix substrate disclosed in PTL 2. The inspecting apparatus according to PTL 2 applies a voltage between scanning lines 81 to 85 and signal lines 91 to 95 of the active matrix substrate, and detects a short-circuit fault 73 that occurs at an intersection of the scanning lines 81 to 85 and the signal lines 91 to 95.

In a normal state, the scanning lines 81 to 85 and the signal lines 91 to 95 are insulated from each other. Thus, no currents flow even if a voltage is applied between the scanning lines 81 to 85 and the signal lines 91 to 95. On the other hand, in a case where the short-circuit fault 73 of the scanning lines 81 to 85 and the signal lines 91 to 95 exists, a current flows through the short-circuit fault 73, and the short-circuit portion and the wiring line through which the current has flown generate heat, so as to generate infrared. An infrared image is captured, image processing is performed on an image signal, and a heat generation region is identified. Further, image processing is performed on the identified heat generation region to specify a heat generation wiring path, and the position of the short-circuit fault portion is detected. In a case where a heat generation region is unidentifiable, the substrate is determined to be a good substrate with no short-circuit faults.

### CITATION LIST

### Patent Literature

PTL 1: Japanese Unexamined Patent Application Publication No. 11-337454 (published on Dec. 10, 1999)

PTL 2: Japanese Unexamined Patent Application Publication No. 6-51011 (published on Feb. 25, 1994)

### SUMMARY OF INVENTION

### Technical Problem

However, in a case where heat is generated in a short-circuit portion and a wiring line, as in PTL 1 and PTL 2, heat conduction causes a rise in temperature in the vicinity thereof. Thus, an identified heat generation region includes the short-circuit portion, the wiring line, and the region in the vicinity thereof. Accordingly, the short-circuit portion is buried in the heat generation region, and an accurate position of the short-circuit portion cannot be specified disadvantageously.

An object of the present invention is to accurately specify the position of a short-circuit portion by binarizing an infrared image of a wiring line including the short-circuit portion and generating a thinned binarized image.

### Solution to Problem

To solve the above-described problem, a wiring inspecting method according to the present invention is a wiring inspecting method for inspecting presence/absence of a short-circuit portion of a wiring line formed on a substrate, including a heat generation process of generating heat in the short-circuit portion by applying a voltage to the wiring line; an image acquisition process of acquiring an infrared image of the substrate; a binarization process of generating a binarized image from the infrared image by using a threshold; and a position specification process of specifying a position of the short-circuit portion by using the binarized image. In the binarization process, binarization processing is repeated by changing the threshold.

A wiring inspecting apparatus according to the present invention is a wiring inspecting apparatus for inspecting presence/absence of a short-circuit portion of a wiring line formed on a substrate, including voltage application means for generating heat in the short-circuit portion by applying a voltage to the wiring line; image capturing means for capturing an infrared image of the substrate; and image processing means for generating a binarized image from the infrared image by using a threshold, and specifying a position of the short-circuit portion. The image processing means includes a binarized image forming unit that repeats binarization processing by changing the threshold.

A wiring inspecting program according to the present invention is a wiring inspecting program for implementing the wiring inspecting method, the wiring inspecting program causing a computer to execute the individual processes.

A computer-readable recording medium according to the present invention includes the wiring inspecting program recorded thereon.

### Advantageous Effects of Invention

According to the wiring inspecting method, wiring inspecting apparatus, wiring inspecting program, and recording medium of the present invention, the position of a short-circuit portion can be accurately specified by binarizing an infrared image of a wiring line including the short-circuit portion and generating a thinned binarized image.

### BRIEF DESCRIPTION OF DRAWINGS

FIG. 1 is a schematic diagram illustrating an inspecting apparatus according to the present invention.

FIG. 2 is a configuration diagram of an image processing unit of the inspecting apparatus according to the present invention.

FIG. 3 is an inspection flowchart illustrating an inspecting method according to the present invention.

FIG. 4 includes plan views illustrating infrared images captured before and after heat is generated.

FIG. 5 is a plan view illustrating an image generated by binarizing an infrared image captured after heat is generated.

FIG. 6 illustrates a thinned binarized image and a brightness-value histogram obtained from the characteristic region thereof.

FIG. 7 illustrates a thinned binarized image and a brightness-value histogram obtained from the characteristic region thereof.

FIG. 8 is a plan view illustrating an image generated by binarizing an infrared image captured after heat is generated.

FIG. 9 includes explanatory diagrams describing cases where a short-circuit position is specified using a binarized image.

FIG. 10 is a perspective view illustrating the configuration of an inspecting apparatus for a wiring pattern according to the related art.

FIG. 11 is a diagram illustrating the configuration of an inspecting apparatus for a wiring pattern according to the related art.

### DESCRIPTION OF EMBODIMENTS

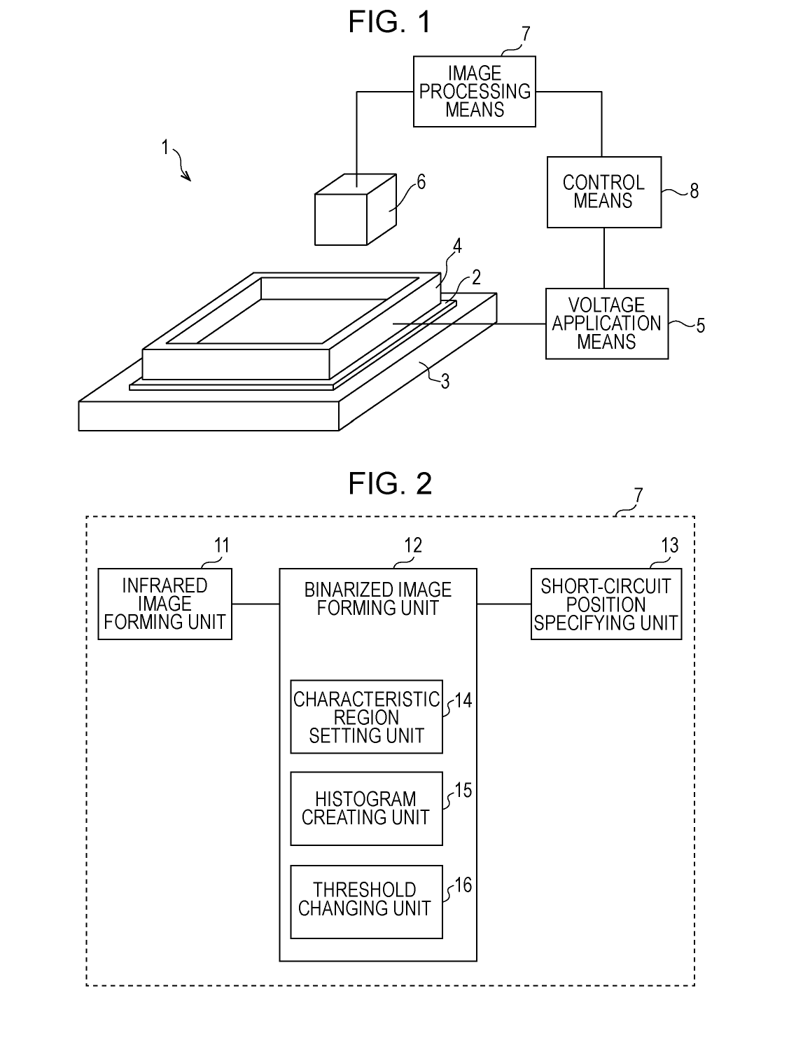

Hereinafter, an embodiment of the present invention will be described in detail with reference to FIGS. 1 to 9. Note that the same reference numerals in the figures of the present invention denote the same parts or corresponding parts.

FIG. 1 is a schematic diagram of a wiring inspecting apparatus 1 according to an embodiment of the present invention. A substrate member 2 as a substrate to be inspected is placed on a mount 3, and a frame body 4 is placed thereon. On the bottom surface of the frame body 4 (the surface which is in contact with the substrate member 2), a plurality of terminals connected to voltage application means 5 are provided. The terminals of the frame body 4 are pressed to be in contact with terminals of a plurality of wiring lines (described below) provided around the substrate member 2. A predetermined voltage is applied to the plurality of wiring lines from the voltage application means 5 via the terminals of the frame body 4.

Image capturing means 6 is placed above the mount 3, and captures an infrared image of the substrate member 2 in a state where a certain voltage is applied. The image capturing means 6 is formed of, for example, an infrared camera that receives infrared emitted from the surface of the substrate member 2 and forms an infrared image. Image data of an infrared image captured by the image capturing means 6 is transmitted to a computer, for example, and is supplied to image processing means 7 via an analog/digital conversion circuit. Control means 8 controls the voltage application means 5 and the image processing means 7 so as to sequentially execute the above-described voltage application, image capturing, and image processing described below.

FIG. 2 is a configuration diagram of the image processing means 7. The image processing means 7 includes an infrared image forming unit 11 that forms an infrared image, a binarized image forming unit 12 that forms a binarized image, and a short-circuit position specifying unit 13 that specifies a short-circuit position using a binarized image.

The infrared image forming unit 11 determines an image contrast in accordance with the amount of radiated infrared, by using captured image data, and forms an infrared image, which is a grayscale image of 256 levels, for example. Regarding the infrared image, for example, as the amount of infrared radiated from an arbitrary point of the surface of the substrate member 2 increases, the brightness value of the image becomes closer to a value corresponding to white.

The binarized image forming unit 12 forms, from the infrared image formed by the infrared image forming unit 11, a binarized image while optimizing a threshold. In the binarized image, a temperature region corresponding to a threshold or less in the infrared image is removed, and a heat generation region including a short-circuit fault is narrowed down.

The short-circuit position specifying unit 13 analyzes the binarized image formed by the binarized image forming unit 12, and specifies the position of a short-circuit fault on the basis of the shape of the heat generation region.

The binarized image forming unit 12 includes, in order to optimize the threshold in accordance with a heat generation region, a characteristic region setting unit 14 that sets a characteristic region that is predicted to include a short-circuit portion, a histogram creating unit 15 that creates a histogram of brightness values of the characteristic region, and a threshold changing unit 16 that changes the threshold on the basis of a result of the histogram.

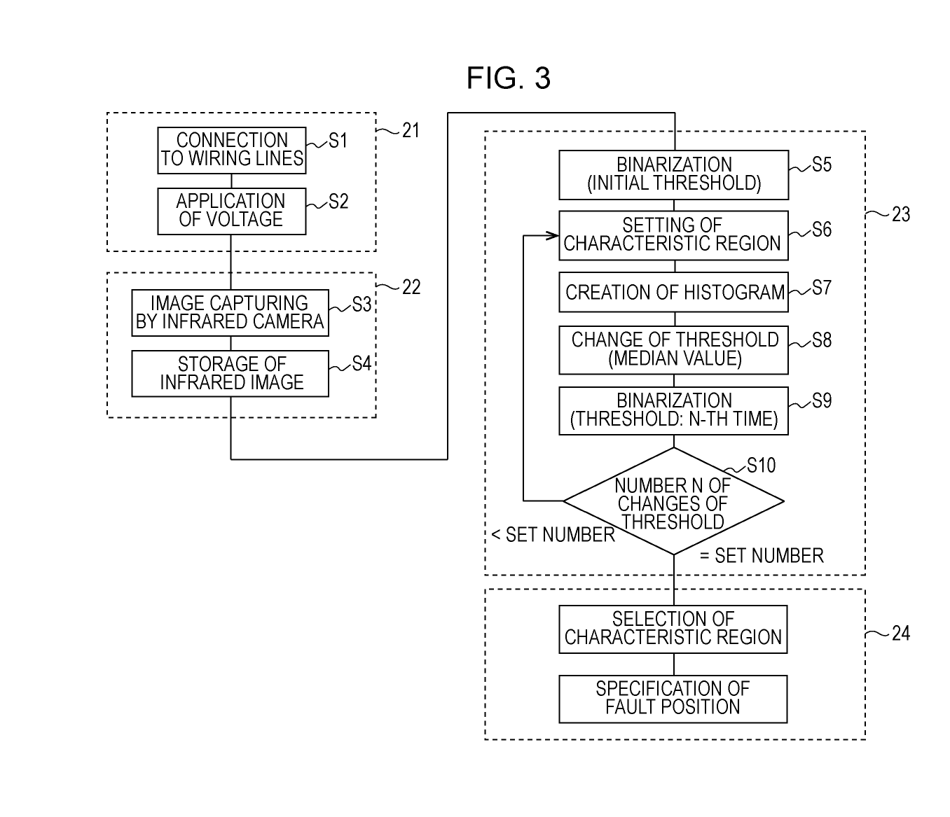

FIG. 3 is a flowchart illustrating a wiring inspecting method that is implemented by the image processing means 7 illustrated in FIG. 2. The wiring inspecting method illustrated in FIG. 3 is recorded as a program on a recording medium, and is stored in a computer-readable manner.

The wiring inspecting method according to the present invention includes a heat generation process 21 of applying a voltage to a wiring line and generating heat in a short-circuit portion, an image acquisition process 22 of capturing, using an infrared camera, an image of the wiring line and short-circuit portion in which heat is generated in the heat generation process 21 and acquiring an infrared image, a binarization process 23 of converting the infrared image to a binarized image using a threshold corresponding to a heat generation region, and a position specification process 24 of specifying the position of the short-circuit portion using the binarized image.

The wiring inspecting method according to the present invention is particularly characterized in that binarization processing is repeated with the threshold being optimized in accordance with a heat generation region in the binarization process 23 so that the heat generation region of an infrared image is thinned.

Hereinafter, the individual processes of the wiring inspecting method illustrated in FIG. 3 will be described in detail.

The heat generation process 21 includes step S1, in which the terminals of the frame body 4 provided around the substrate member 2 are pressed to be connected to wiring lines, and step S2, in which a certain voltage is applied to wirings or between wirings from the voltage application means 5 via the terminals of the frame body 4. The voltage to be applied varies in accordance with a resistance value of a wiring line or a short-circuit portion. It is assumed that, for example, a voltage value is 50 V and an application period is 5 seconds.

The image acquisition process 22 includes step S3, in which an image of the substrate member 2 having a short-circuit portion generating heat is captured by the image capturing means 6 such as an infrared camera so as to acquire an infrared image, and step S4, in which the captured infrared image is stored in a storage device such as a memory.

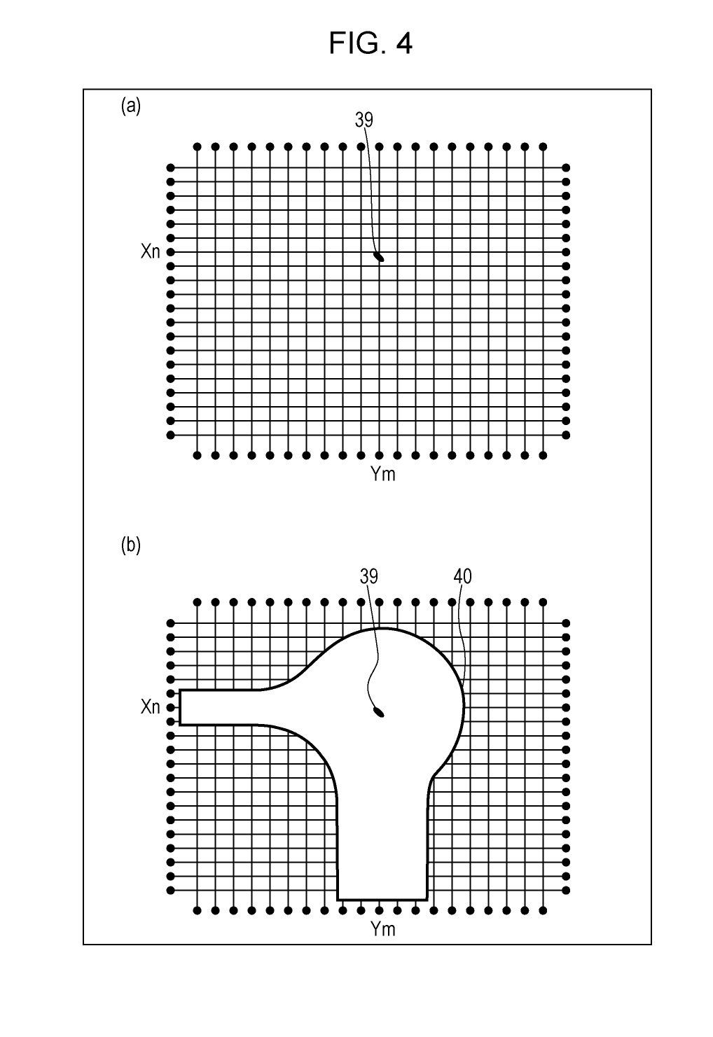

FIG. 4 illustrates an example of infrared images obtained by shooting the substrate member 2. In the substrate member 2, a plurality of wiring lines X formed in an X direction and wiring lines Y formed in a Y direction intersect each other via an insulator. Thin film transistors (TFTs) or the like serving as switching elements (not illustrated) are formed at individual intersection portions. FIG. 4 illustrates a case where a short-circuit portion 39 is generated at the intersection of the n-th wiring line Xn and the m-th wiring line Ym. Part (a) of FIG. 4 illustrates an infrared image before a voltage is applied between the wiring lines, and part (b) of FIG. 4 illustrates an infrared image of a heat generation region 40 that is generated by heat generation in the short-circuit portion 39 after a voltage is applied between the wiring lines. In the following figures illustrating an infrared image including FIG. 4, the wiring lines X and wiring lines Y are superposed on an infrared image for easy understanding.

As illustrated in part (b) of FIG. 4, the heat generation region 40 is formed along a short-circuit path including the wiring line Xn, the short-circuit portion 39, and the wiring line Ym. The temperature increases as the resistance value increases, and the heat generation region 40 has a considerably wide area around the short-circuit portion 39. Thus, binarization processing for removing a noise component from the infrared image is performed in a ordinary case.

Here, a temperature rise +Δ° C. caused by noise is predetermined to be a constant multiple of a standard deviation of the noise, for example, 0.1 to 0.5° C. With the substrate temperature before heat generation plus Δ° C. being an initial threshold, the infrared image is converted to a binarized image to remove noise. A pixel in which the temperature exceeds the initial threshold is determined to be a pixel in which a significant temperature rise has occurred. However, since the initial threshold is a relatively small value, the heat generation region 40 still has a wide area, and it is difficult to accurately specify the position of the short-circuit portion 39. Thus, there is a probability that an intersection near the short-circuit portion 39 is wrongly determined to be the position of the short-circuit portion 39.

In addition, there is an influence of change in temperature caused by noise, and thus the position of a pixel having the maximum temperature is not always a short-circuit portion. Accordingly, if the infrared image is binarized using a binarization threshold which is slightly lower than the maximum temperature of the infrared image, a binarized image of a small region including the pixel having the highest temperature is acquired.

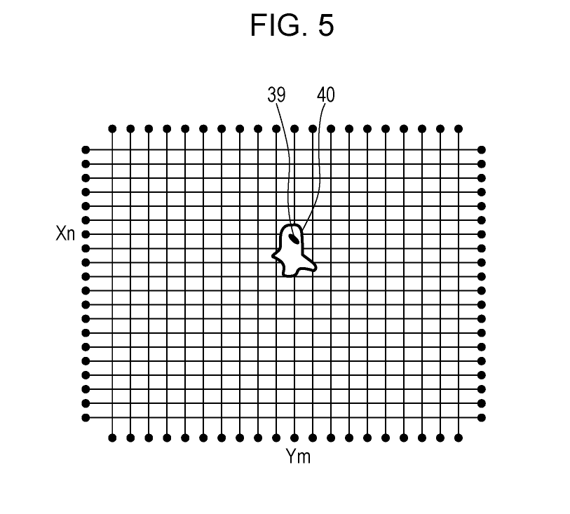

FIG. 5 illustrates a binarized image acquired through binarization performed using a binarization threshold which is slightly lower than the maximum temperature. The binarization threshold is, for example, the maximum temperature minus Δ° C. This binarized image has completely lost information indicating the wiring path in which heat is generated. Therefore, it is difficult to specify the position of the short-circuit portion using this binarized image, and also it is difficult to specify which wiring path has generated heat.

The number of short-circuit portions is not always one, but may be two or more. In such a case, if the infrared image is binarized using a binarization threshold which is slightly lower than the maximum temperature of the infrared image, a short-circuit portion near the position of the maximum temperature remains, but the other short-circuit portions are removed and not found disadvantageously.

As described above, a binarization threshold which is set to any of a relatively small value, such as the substrate temperature before heat generation plus Δ° C., and a relatively large value, such as the maximum temperature minus Δ° C., is inappropriate to specify the position of the short-circuit portion 39.

Therefore, in the binarization process 23, binarization processing is repeated by optimizing the threshold, and thereby the heat generation region 40 including the short-circuit portion 39 is thinned so that the position of the short-circuit portion 39 is easily specified.

In the binarization process 23, first, in step S5, binarization processing is performed using a preset initial threshold. The initial threshold is, for example, the substrate temperature before heat generation plus Δ° C. In step S5, background noise of the infrared image is removed.

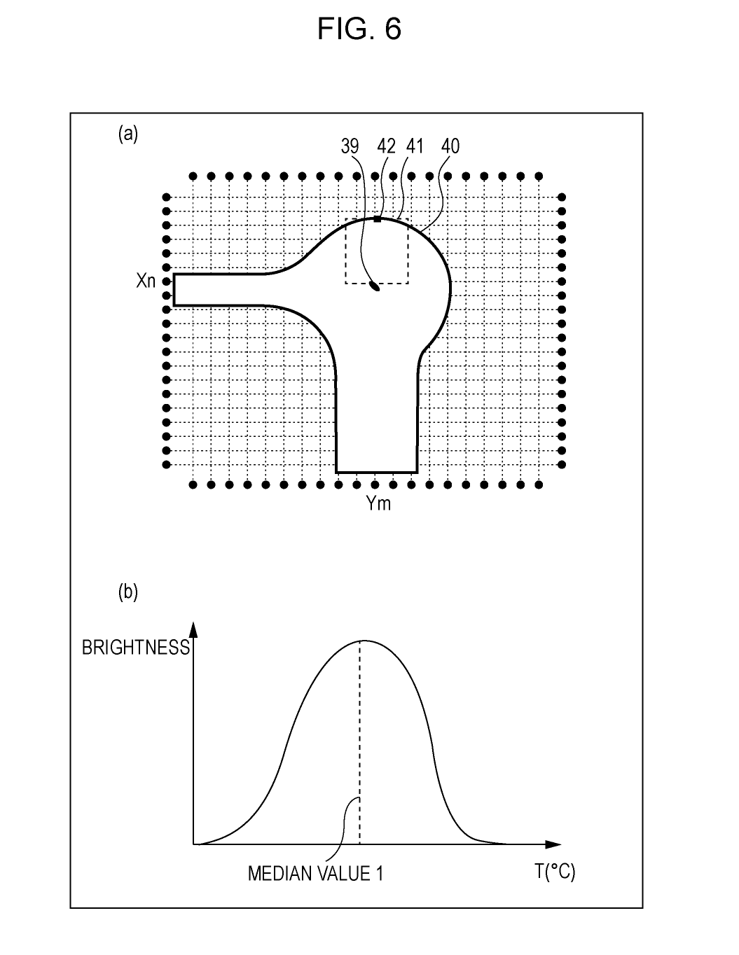

Part (a) of FIG. 6 illustrates an image acquired by converting the infrared image illustrated in part (b) of FIG. 4 to a binarized image through binarization processing in step S5. In the binarized image illustrated in part (a) of FIG. 6, a temperature region corresponding to the initial threshold or less has been removed, and thinning has been performed to some extent, which is still insufficient.

Subsequently, the threshold is optimized to further performing thinning on the heat generation region 40 including the short-circuit portion 39. First, in step S6, a characteristic region 41 including the short-circuit portion 39 is predicted in the binarized image illustrated in part (a) of FIG. 6. Depending on the degree of heat generation, the short-circuit portion 39 is not always included in the predicted characteristic region 41 (the prediction is not always correct), but this not a problem because a further process is performed.

To predict the characteristic region 41, an end pixel 42 of the heat generation region 40 is first specified. In a case where there are a plurality of end pixels, that is, in a case where there is a line segment, the median pixel of the line segment may be regarded as the end pixel 42. In a case where there are two or more line segments, a median value of the coordinates of the plurality of pixels may be used. Subsequently, with the end pixel 42 being the center of an upper side, a rectangular region having a certain size is set as the characteristic region 41.

As the size of the characteristic region 41, the number of pixels corresponding to a heat generation region generated by heat conduction from the start of heat generation to capturing of an infrared image may be set. For example, the characteristic region 41 may be a square formed of 5×5 pixels.

Alternatively, the certain size of the characteristic region 41 may be appropriately adjusted in accordance with the time period from the start of heat generation to capturing of an infrared image. That is, in a case where the time period from the start of heat generation to capturing of an infrared image is short, the size of the characteristic region 41 is decreased, that is, in a case where the time period from the start of heat generation to capturing of an infrared image is long, the size of the characteristic region 41 is increased.

Alternatively, the characteristic region 41 may be circular. In a case where the amount of heat generation is larger in a short-circuit portion than in a wiring portion, heat is generated in a circular region with the short-circuit portion being the center, and thus it is desirable that the characteristic region 41 be circular. For example, the characteristic region 41 may be a circle whose diameter corresponds to five pixels.

Subsequently, in step S7, a histogram is generated using the brightness values of the characteristic region 41. Accordingly, brightness value information regarding the vicinity of the short-circuit portion 39 can be acquired.

Part (b) of FIG. 6 illustrates a histogram of the brightness values of the characteristic region 41 illustrated in part (a) of FIG. 6. In step S8, a median value for dividing the area of the histogram into two halves is acquired, and the initial threshold is replaced with the median value as a new threshold.

Subsequently, in step S9, binarization processing is performed again on the infrared image illustrated in part (b) of FIG. 4 using the changed threshold.

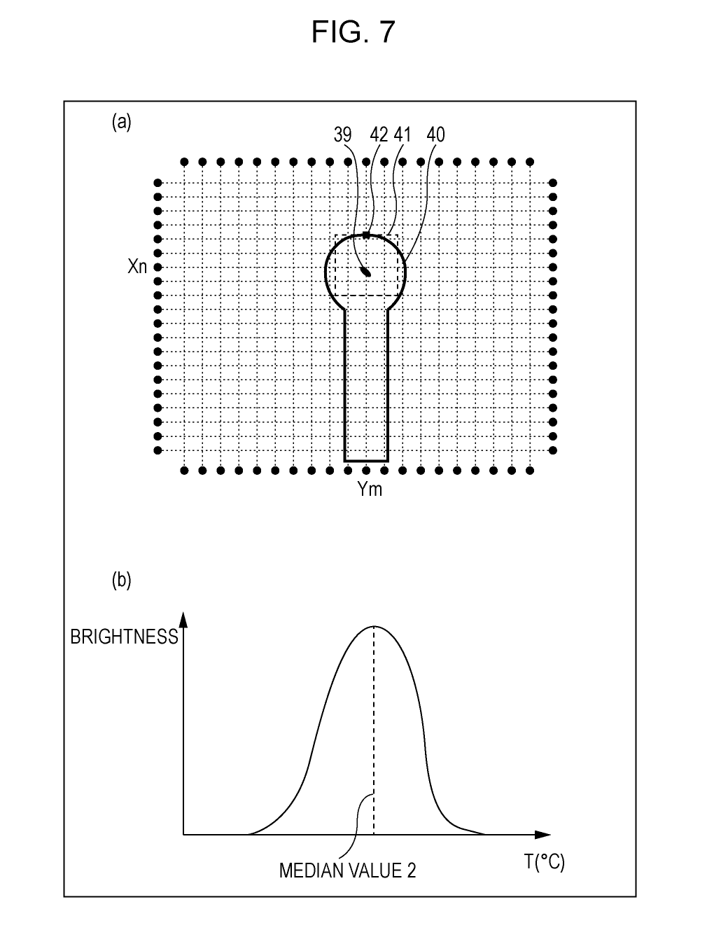

Part (a) of FIG. 7 illustrates a binarized image generated using the changed threshold. The changed threshold is a value that is more approximate to the temperature of the short-circuit portion 39 than the initial threshold, and thus the binarized image acquired after the threshold has been changed is more thinned than the binarized image generated using the initial threshold. Since the median value is set as the new threshold, the area of the characteristic region 41 illustrated in part (a) of FIG. 7 is half in the new binarized image. Also, the area of the new heat generation region 40 illustrated in part (a) of FIG. 7 is almost the half of the area of the previous heat generation region 40 illustrated in part (a) of FIG. 6.

That is, if the shape of the histogram of the characteristic region 41 illustrated in part (b) of FIG. 7 completely matches the shape of the histogram of the heat generation region 40 illustrated in part (b) of FIG. 6, the area of the heat generation region 40 illustrated in part (a) of FIG. 7 matches the half of the area of the heat generation region 40 illustrated in part (a) of FIG. 6. However, it is rare that the histograms completely match, and the histograms are similar to each other in a usual case, and thus the area is almost the half. In this way, since the area is almost the half, the binarized image after the threshold has been changed is thinned compared to the binarized image based on the initial threshold.

Subsequently, in step S10, the number of times the threshold was changed is judged, and change of the threshold and binarization processing are repeated a certain number of times.

In a case where the number of times the threshold was changed has not reached the certain number of times, it is judged that the threshold has not sufficiently been optimized, and the process returns to step S6. In step S6, as in the previous time, a region corresponding to 5×5 pixels from the end pixel 42 of the heat generation region 40 is set again as a new characteristic region 41 by using the binarized image illustrated in part (a) of FIG. 7, and the histogram of the new characteristic region 41 is generated. If the certain number of times is too large, the binarization threshold becomes too large, and it becomes difficult to specify the position of a short-circuit portion as illustrated in FIG. 5. Thus, it is preferable to adjust an appropriate certain number by performing experiments.

Part (b) of FIG. 7 illustrates the histogram of the new characteristic region 41. As illustrated in part (b) of FIG. 7, in the histogram of the new characteristic region 41, a median value shifts to the high-temperature side, and it is indicated that the brightness value information of the short-circuit portion 39 is narrowed down. In this way, the threshold is changed to an optimal threshold by narrowing down the brightness value information regarding the short-circuit portion 39 in the characteristic region 41, and thereby the binarized image can be thinned.

The threshold is changed at least twice, and thereby the binarized image can be thinned so that the position of the short-circuit portion 39 can be specified. In a case where the threshold is changed twice or more to further thin the binarized image, the process may be finished by judging that the binarized image has sufficiently been thinned when the median value becomes smaller than the previous threshold.

Step S7 of generating a histogram may be omitted. That is, in step S8, a median value may be directly calculated from the pixel values of the characteristic region set in step S5, and the threshold may be changed.

The median value of the characteristic region 41 is used as a new binarization threshold, but the new binarization threshold is not limited thereto. A certain percentile value may be used as a new binarization threshold. Regarding percentile, when brightness values are sorted in ascending order, a value at 100p % (0≦p≦1) from the smallest value is referred to as 100p percentile.

For example, if a 75 percentile value is used as a binarization threshold, the area of the heat generation region 40 can be reduced to about a quarter. A median value is equal to a 50 percentile value (p=0.5). By using a percentile value of p>0.5, the certain number of changes of the threshold can be easily reduced, and the processing time of the binarization process 23 can be shortened.

However, the number of pixels in the characteristic region 41 is smaller than the number of pixels in the heat generation region 40, and thus the 75 percentile value of the characteristic region 41 is not equal to the 75 percentile value of the heat generation region 40. There is a risk that the 75 percentile value of the characteristic region 41 is larger than the 75 percentile value of the heat generation region 40. Thus, it is desired that the median value of the characteristic region 41 be used as a new binarization threshold.

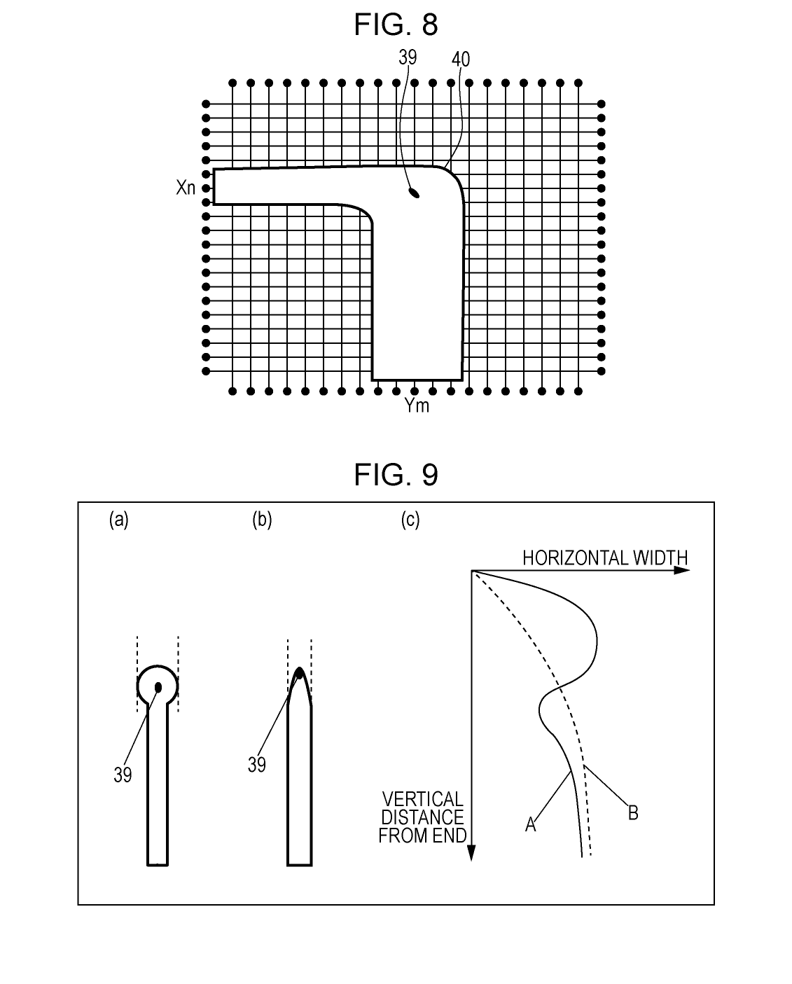

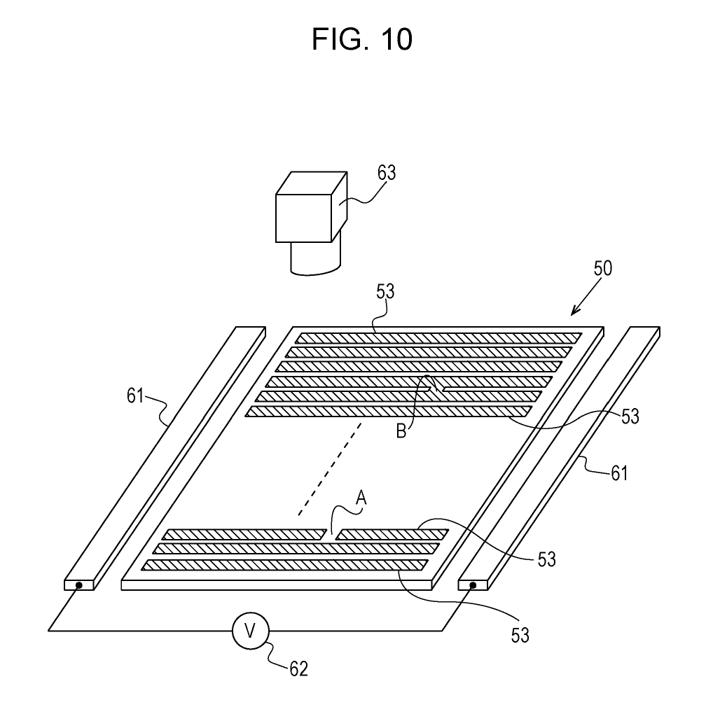

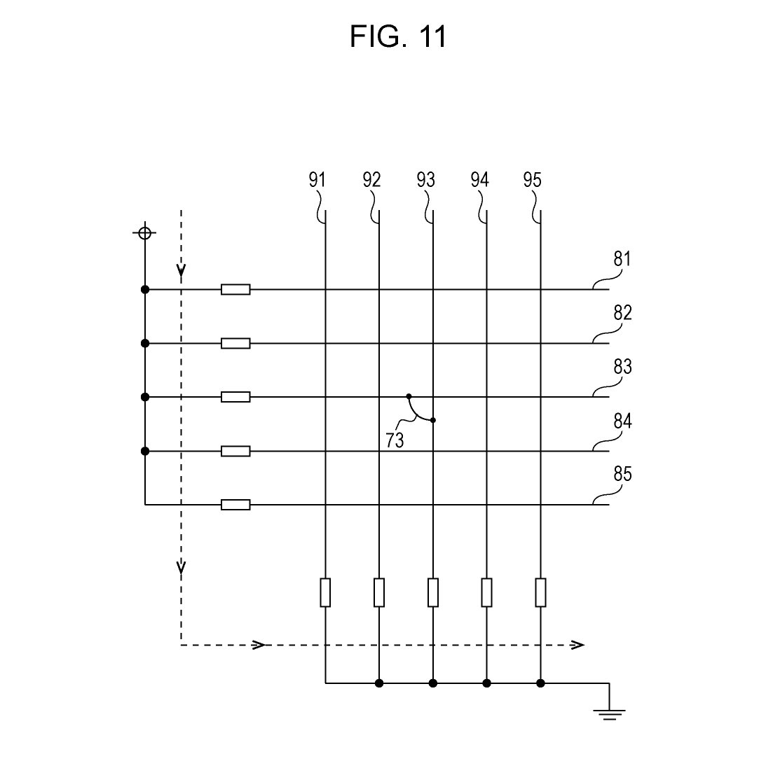

FIG. 8 illustrates another example of an infrared image acquired by shooting the substrate member 2. The heat generation region 40 is formed along a short-circuit path including a wiring line Xn, a short-circuit portion 39, and a wiring line Ym, and the width thereof is larger in a portion where the resistance value is larger due to an increase in temperature. In the case of the infrared image illustrated in FIG. 8, the amount of heat generation in the short-circuit portion 39 is small compared to part (b) of FIG. 4, and the size of the region near the short-circuit portion 39 is relatively small.

Parts (a) and (b) of FIG. 9 illustrate examples of a thinned binarized image. The shape of a thinned binarized image may be a matchstick-shaped heat generation shape illustrated in part (a) of FIG. 9, or may be a pencil-shaped heat generation shape illustrated in part (b) of FIG. 9, in accordance with a tradeoff between a wiring resistance value and a resistance value of a short-circuit portion. For example, the infrared image illustrated in part (b) of FIG. 4 becomes the thinned binarized image illustrated in part (a) of FIG. 9, and the infrared image illustrated in FIG. 8 becomes the thinned binarized image illustrated in part (b) of FIG. 9. Depending on such a difference in heat generation shape, a method for specifying the position of the short-circuit portion 39 varies. A difference in heat generation shape can be judged by measuring a horizontal width from the end of the heat generation region, as illustrated in part (c) of FIG. 9.

The position of a short-circuit portion can be specified using a thinned binarized image and an image processing method according to the related art. For example, in the case of a matchstick-shaped heat generation shape, the position of a short-circuit portion can be specified in the procedure of identifying and extracting a circular portion at the end, and calculating a barycenter. Also, in the case of a pencil-shaped heat generation shape, the position of a short-circuit portion can be specified in the procedure of a binarized image, thinning, and the end pixel of a thin line.

The temperature measured by the infrared camera is affected by the emittance of an object whose image is captured. On the substrate, objects having different emittances, such as wiring materials of glass, chromium, aluminum, copper, and so forth, are formed. Thus, the substrate temperature on the substrate is not uniform on the entire surface. Thus, it is necessary to remove the influence of emittance in order to capture an image representing heat generation with high accuracy. For this purpose, images captured before and after voltage application may be detected, and the difference therebetween may be detected. That is, image capturing is performed in the following procedure.

(1) Perform image capturing before heat is generated (before voltage is applied), so as to acquire a first image.

(2) Apply a voltage to generate heat.

(3) Capture an image to acquire a second image.

(4) Subtract the first image from the second image (calculate the differences between pixel values of individual pixels), so as to calculate a difference image.

(5) Perform binarization process 23 and the subsequent process on the difference image.

The pixel value of the difference image represents the temperature that has increased due to heat generation. The initial threshold may be Δ° C.

The embodiment of the present invention has been described above. The present invention is not limited to the above-described embodiment, and various changes can be made within the scope of the claims. An embodiment that is obtained by appropriately combining technical means disclosed in different embodiments is included in the technical scope of the present invention.

As described above, in the wiring inspecting method according to the present invention, a binarization process is characterized by predicting a characteristic region including a short-circuit portion from a binarized image, and changing the threshold of the next binarization processing to a certain percentile value of the characteristic region.

In the wiring inspecting method according to the present invention, it is characterized that repetition of binarization processing is finished when the certain percentile value of the characteristic region is smaller than or equal to the threshold.

In the wiring inspecting method according to the present invention, it is characterized that the certain percentile value is a median value.

In the wiring inspecting method according to the present invention, it is characterized that the characteristic region is a circle or a rectangle having a certain size.

### INDUSTRIAL APPLICABILITY

The present invention is favorably applicable to a wiring inspecting method and a wiring inspecting apparatus for detecting a short-circuit fault of a wiring line on a substrate on which a plurality of wiring lines are formed, such as an active matrix substrate used for, for example, a liquid crystal display apparatus.

### REFERENCE SIGNS LIST

1 inspecting apparatus
2 substrate member (substrate)
3 mount
4 frame body
5 voltage application means
6 image capturing means
7 image processing means
8 control means
11 infrared image forming unit
12 binarized image forming unit
13 short-circuit position specifying unit
14 characteristic region setting unit
15 histogram creating unit
16 threshold changing unit
39 short-circuit portion
X•Xn wiring line
Y•Ym wiring line

1-9. (canceled)

10. A wiring inspecting method for inspecting presence/absence of a short-circuit portion of a wiring line formed on a substrate, comprising:
a heat generation process of generating heat in the short-circuit portion by applying a voltage to the wiring line;
an image acquisition process of acquiring an infrared image of the substrate;
a binarization process of generating a binarized image from the infrared image by using a threshold; and
a position specification process of specifying a position of the short-circuit portion by using the binarized image,
wherein, in the binarization process, binarization processing is repeated by changing the threshold.

11. The wiring inspecting method according to claim 10, wherein the binarization process includes
predicting a characteristic region including the short-circuit portion by using the binarized image, and
changing the threshold, for next binarization processing, to a certain percentile value of the characteristic region.

12. The wiring inspecting method according to claim 11, wherein repetition of the binarization processing is finished in a case where the certain percentile value of the characteristic region is smaller than or equal to a threshold used previous time.

13. The wiring inspecting method according to claim 11, wherein the certain percentile value is a median value.

14. The wiring inspecting method according to claim 12, wherein the certain percentile value is a median value.

15. The wiring inspecting method according to claim 11, wherein the characteristic region is a certain circle or rectangle.

16. A wiring inspecting apparatus for inspecting presence/absence of a short-circuit portion of a wiring line formed on a substrate, comprising:
voltage application means for generating heat in the short-circuit portion by applying a voltage to the wiring line;
image capturing means for capturing an infrared image of the substrate; and
image processing means for generating a binarized image from the infrared image by using a threshold, and specifying a position of the short-circuit portion;
wherein the image processing means includes a binarized image forming unit that repeats binarization processing by changing the threshold.

17. A computer-readable and non-transitory recording medium on which a wiring inspecting program is recorded, the wiring inspecting program implementing a wiring inspecting method for inspecting presence/absence of a short-circuit portion of a wiring line formed on a substrate,
the wiring inspecting program causing a computer to execute:
a heat generation process of generating heat in the short-circuit portion by applying a voltage to the wiring line;
an image acquisition process of acquiring an infrared image of the substrate;
a binarization process of generating a binarized image from the infrared image by using a threshold; and
a position specification process of specifying a position of the short-circuit portion by using the binarized image,
wherein, in the binarization process, binarization processing is repeated by changing the threshold.
